(19) United States
(12) Patent Application Publication
(10) Pub. No.: US 2026/0096468 A1
(43) Pub. Date: Apr. 2, 2026

(54) SEMICONDUCTOR PACKAGE

(71) Applicant: SAMSUNG ELECTRONICS CO., LTD., Suwon-si (KR)

(72) Inventors: Harim NOH, Suwon-si (KR); Eunkyeong Park, Suwon-si (KR); Seokbeom Yong, Suwon-si (KR)

(73) Assignee: SAMSUNG ELECTRONICS CO., LTD., Suwon-si (KR)

(21) Appl. No.: 19/201,540

(22) Filed: May 7, 2025

(30) Foreign Application Priority Data
Oct. 2, 2024 (KR) 10-2024-0133995

(51) Int. Cl. H01L 23/31; H01L 21/56; H01L 23/00; H01L 23/29; H01L 23/498

(52) U.S. Cl. CPC H10W 74/121; H10W 70/65; H10W 70/685; H10W 74/016; H10W 74/117; H10W 74/43; H10W 72/923; H10W 72/9415; H10W 74/40; H10W 90/724

(57) ABSTRACT

A semiconductor package may include: a redistribution structure; a semiconductor chip on the redistribution structure; and a molding film around the semiconductor chip. The molding film may include: a first molding layer having a first dielectric constant; and a second molding layer having a second dielectric constant that is smaller than the first dielectric constant.

### CROSS-REFERENCE TO RELATED APPLICATION

This application claims priority to and the benefit of Korean Patent Application No. 10-2024-0133995 filed on Oct. 2, 2024, in the Korean Intellectual Property Office, disclosure of which is incorporated by reference herein in its entirety.

### BACKGROUND

### 1. Field

The present disclosure relates to a semiconductor package.

### 2. Description of the Related Art

Semiconductor packages play an important role in protecting semiconductor chips, insulating the chips from an external environment, and ensuring electrical connections. Among semiconductor packaging processes, a molding process is mainly used to protect the chips from external impacts, moisture, dust, etc. In this process, a molding material acts as a seal by wrapping the semiconductor chip and the circuit board, and provides a thermal and mechanical stability.

As the semiconductor devices accelerate toward a higher performance and integration, they consume more electric power, and the resulting a heat generation problem is becoming more serious. These heating issues may cause a performance degradation of the device and, in the long term, reduce the reliability and lifespan of the device. In particular, a thermal management is emerging as a very important factor in a packaging design for modern semiconductor devices that require high speed operation and large-scale data processing.

Various heat dissipation technologies are being developed to effectively handle the heat generation in the semiconductor packages, and particularly high dielectric constant (high-k) molding films are attracting attention as materials that may improve the heat dissipation performance of the semiconductor packages. However, since there is a problem that a signal integrity characteristic is degraded when the high dielectric constant molding film is applied to the semiconductor package, a research is being conducted to improve the signal integrity characteristic in the semiconductor devices that require a high-rate data transmission.

### SUMMARY

One or more embodiments provide a semiconductor package that may improve heat dissipation characteristics and maintain signal integrity characteristics in the semiconductor package requiring a miniaturization and a high performance.

According to an aspect of the disclosure, a semiconductor package may include: a redistribution structure; a semiconductor chip on the redistribution structure; and a molding film around the semiconductor chip. The molding film may include: a first molding layer having a first dielectric constant; and a second molding layer having a second dielectric constant that is smaller than the first dielectric constant.

According to an aspect of the disclosure, a semiconductor package may include: a semiconductor chip including: a semiconductor substrate including an active layer; a power/ground chip pad on a lower surface of the semiconductor substrate; and a signal chip pad on the semiconductor substrate. The semiconductor package may further include a redistribution structure supporting the semiconductor chip including: a substrate insulation layer; a plurality of signal line patterns inside the substrate insulation layer and connected to the signal chip pad; and a plurality of power/ground line patterns inside the substrate insulation layer on a same level as the plurality of signal line patterns and connected to the power/ground chip pad. The semiconductor package may further include: a first molding layer around the semiconductor chip on the redistribution structure and having a first dielectric constant; and a second molding layer having a second dielectric constant that is smaller than the first dielectric constant.

According to an aspect of the disclosure, a manufacturing method of a semiconductor package, may include: arranging a semiconductor chip on a redistribution structure; electrically connecting a chip pad of the semiconductor chip and a substrate pad of the redistribution structure through a connection terminal; and forming a molding film around the semiconductor chip on the redistribution structure. The molding film may include a first molding layer having a first dielectric constant and a second molding layer having a second dielectric constant that is smaller than the first dielectric constant.

According to one or more embodiments, by providing the first molding layer including a high-dielectric material and the second molding layer including a low-dielectric material together in the molding film protecting the semiconductor chip, heat dissipation characteristics may be improved while also improving signal transmission characteristics.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a top plan view of a semiconductor package according to one or more embodiments;

FIG. 2 is a cross-sectional view taken along a line A-A′ of FIG. 1 according to one or more embodiments;

FIG. 3 is a cross-sectional view taken along a line B-B′ of FIG. 1 according to one or more embodiments;

FIG. 4 is a cross-sectional view taken along a line A-A′ of FIG. 1 according to one or more embodiments;

FIG. 5 is a cross-sectional view taken along a line A-A′ of FIG. 1 according to one or more embodiments;

FIG. 6 is a top plan view of a semiconductor package according to one or more embodiments;

FIG. 7 is a cross-sectional view taken along a line C-C′ of FIG. 6 according to one or more embodiments;

FIG. 8 is a top plan view of a semiconductor package according to one or more embodiments;

FIG. 9 is a cross-sectional view taken along a line D-D′ of FIG. 8 according to one or more embodiments;

FIG. 10 is a top plan view of a semiconductor package according to one or more embodiments;

FIG. 11 is a cross-sectional view taken along a line E-E′ of FIG. 10 according to one or more embodiments;

FIG. 12 is a cross-sectional view taken along a line E-E′ of FIG. 10 according to one or more embodiments;

FIG. 13 is a view for explaining a manufacturing method of a semiconductor package according to one or more embodiments;

FIG. 14 is a view for explaining a manufacturing method of a semiconductor package according to one or more embodiments;

FIG. 15 is a view for explaining a manufacturing method of a semiconductor package according to one or more embodiments;

FIG. 16 is a view for explaining a manufacturing method of a semiconductor package according to one or more embodiments; and FIG. 17 is a table showing an impedance of a signal wire according to a thickness of a second molding layer according to one or more embodiments.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

Descriptions of parts not related to the present disclosure are omitted, and like reference numerals designate like elements throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

As used herein, expressions such as “at least one of,” when preceding a list of elements, modify the entire list of elements and do not modify the individual elements of the list. For example, the expression “at least one of a, b or c” indicates only a, only b, only c, both a and b, both a and c, both b and c, or all of a, b, and c.

Further, in the specification, the phrase “on a plane” means viewing the object portion from the top, and the phrase “on a cross-section” means viewing a cross-section of which the object portion is vertically cut from the side.

In the specification, spatially relative terms such as “top”, “bottom”, “upper”, “lower”, “up”, “down”, “horizontal,” “vertical” etc. are used to easily explain the positional relationship of each component when viewed from a direction depicted in the drawings. Therefore, spatially relative terms indicating the positional relationship of each component may be understood differently when viewed from a direction other than the direction depicted in the drawings.

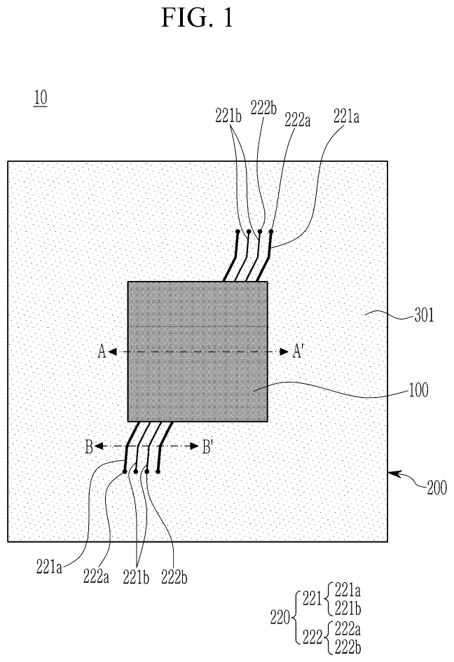

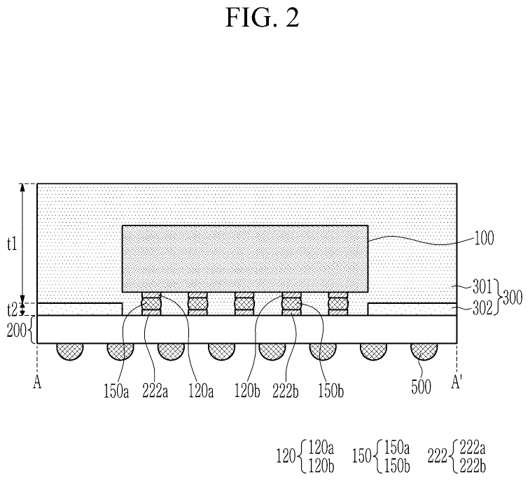

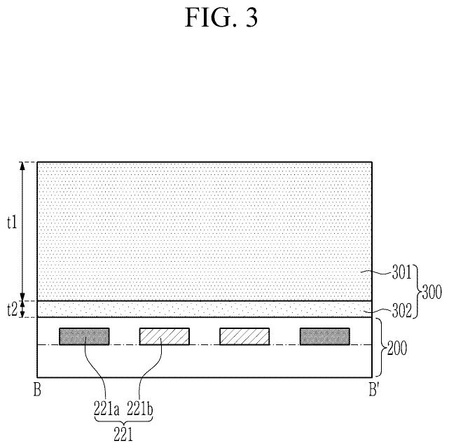

FIG. 1 is a top plan view of a semiconductor package according to one or more embodiments. FIG. 2 is a cross-sectional view taken along a line A-A′ of FIG. 1 according to one or more embodiments. FIG. 3 is a cross-sectional view taken along a line B-B′ of FIG. 1 according to one or more embodiments.

Referring to FIG. 1 to FIG. 3 together, a semiconductor package 10 according to one or more embodiments of the present disclosure may include a semiconductor chip 100, a connection terminal 150, a first redistribution structure 200 (structure), a molding film 300, and an external connection terminal 500.

According to one or more embodiments, the semiconductor chip 100 may include a semiconductor substrate having an active layer, and a chip pad 120 disposed on the lower surface of the semiconductor substrate.

According to one or more embodiments, the semiconductor chip 100 may include a memory semiconductor chip. For example, the memory semiconductor chip may include a volatile memory semiconductor chip such as a dynamic random access memory (DRAM) or a static random access memory (SRAM), and may include a non-volatile memory semiconductor chip such as a phase-change random access memory (PRAM), a magneto-resistive random access memory (MRAM), a ferroelectric random access memory (FeRAM), or a resistive random access memory (RRAM).

However, without a limitation, the semiconductor chip 100 may include a logic semiconductor chip. For example, the logic semiconductor chip may include a logic semiconductor chip such as a central processor unit (CPU), a microprocessor unit (MPU), a graphics processor unit (GPU), or an application processor (AP).

The material of the semiconductor substrate of the semiconductor chip 100 may include silicon (Si). Additionally, the material of the semiconductor substrate may include a semiconductor element such as germanium (Ge), or a compound semiconductor such as silicon carbide (SiC), gallium arsenide (GaAs), indium arsenide (InAs), and indium phosphide (InP). However, the material of the semiconductor substrate is not limited to what was described above.

According to one or more embodiments, the semiconductor substrate may include an active layer thereunder. The active layer may include a plurality of individual devices. For example, the plurality of individual devices may include various micro electronic devices, for example, a complementary metal-oxide semiconductor transistor (CMOS transistor), a metal-oxide-semiconductor field effect transistor (MOSFET), a system LSI (large scale integration), an image sensor such as a CMOS imaging sensor (CIS), a micro-electro-mechanical system (MEMS), active components, and passive components.

In the present disclosure, a horizontal direction may be defined as a direction parallel to a direction along which the upper and lower surfaces of the semiconductor substrate extend, and a vertical direction may be defined as a direction perpendicular to the direction along which the upper and lower surfaces of the semiconductor substrate extend.

According to one or more embodiments, the chip pad 120 disposed on the lower surface of the semiconductor substrate may include a power/ground chip pad 120a and a signal chip pad 120b. The power/ground chip pad 120a of the semiconductor chip 100 may be configured to apply a power voltage of the semiconductor chip 100 or may be provided for a ground. Additionally, the signal chip pad 120b of the semiconductor chip 100 may be provided for transmitting a command signal and/or an address signal of the semiconductor chip 100 or for transmitting a data signal.

According to one or more embodiments, the material of the power/ground chip pad 120a and the signal chip pad 120b may include copper (Cu). However, without being limited to the above, the material of the power/ground chip pad 120a and the signal chip pad 120b may be a metal or an alloy thereof, such as nickel (Ni), gold (Au), silver (Ag), aluminum (Al), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), ruthenium (Ru), etc.

According to one or more embodiments, the power/ground chip pad 120a may be connected to a power/ground chip connection terminal 150a, a power/ground substrate pad 222a, and a power/ground line pattern 221a, which will be described later. Additionally, the signal chip pad 120b may be connected to a signal chip connection terminal 150b, a signal substrate pad 222b, and a signal line pattern 221b, which will be described later.

According to one or more embodiments, the first redistribution structure 200 may support the semiconductor chip 100. According to one or more embodiments, the first redistribution structure 200 may include a printed circuit board (PCB). However, the substrate of the first redistribution structure 200 is not limited to the structure and the material of the printed circuit board (PCB), and may include various types of substrates, such as a ceramic substrate.

According to one or more embodiments, the molding film 300 may be disposed on the first redistribution structure 200. The molding film 300 may surround the semiconductor chip 100 on the first redistribution structure 200. The molding film 300 may surround the connecting terminals 150. The molding film 300 may fill the space between the first redistribution structure 200 and the semiconductor chip 100. According to one or more embodiments, the space between the first redistribution structure 200 and the semiconductor chip 100 may be filled with an under fill material. The side surface of the molding film 300 may be aligned vertically with the side surface of the first redistribution structure 200. For example, molding film 300 may include an insulating polymer, such as an epoxy-based molding compound (EMC). However, it is not limited to this, and the material constituting the molding film 300 may be changed in various ways.

According to one or more embodiments, the molding film 300 may include a first molding layer 301 and a second molding layer 302.

According to one or more embodiments, the first molding layer 301 and the second molding layer 302 may include materials having different dielectric constants. In some embodiments, the first molding layer 301 may include a material having a first dielectric constant, and the second molding layer 302 may include a material having a second dielectric constant different from the first dielectric constant.

For example, the first dielectric constant may be greater than the second dielectric constant. In some embodiments, the first molding layer 301 may include a high-dielectric material having a dielectric constant of greater than about 7. For example, the first dielectric constant may have a value within the range of about 7 to about 1000.

According to one or more embodiments, the first molding layer 301 may include a high-dielectric material having a higher dielectric constant than silicon oxide (SiOx). For example, the first molding layer 301 may include hafnium silicon oxynitride (HfSiON), hafnium oxide (HfO2), zirconium oxide (ZrO2), tantalum oxide (Ta2O5), titanium oxide (TiO2), strontium titanium oxide (SrTiO5) and/or (barium strontium) titanium oxide ((Ba, Sr)TiO5).

According to one or more embodiments, the second molding layer 302 may include a low-dielectric material having a dielectric constant of less than about 7. For example, the second dielectric constant may have a value within a range of about 1 to about 7.

For example, the second molding layer 302 may include a polyimide (polyimide), a silicon (silicon) series material, a polybenzoxazole (polybenzoxazole), and/or an epoxy (epoxy) series material.

As described above, when the molding film 300 includes the first molding layer 301 and the second molding layer 302 having different dielectric constants, heat dissipation characteristics of the semiconductor package 10 may be maintained and simultaneously a desired signal integrity characteristic may be improved.

Specifically, when the first molding layer 301 includes a high-dielectric material as in the present embodiment, the heat dissipation characteristics of the semiconductor package 10 may be maintained, but the capacitance formed between the line patterns 221 described later may increase. In this way, when the capacitance between the line patterns 221 increases, the impedance of the line patterns 221 decreases, so the signal integrity characteristic may be degraded.

At this time, as in the present embodiment, since the second molding layer 302 includes the low-dielectric material, the capacitance formed between the line patterns 221 described later is relatively reduced, thereby preventing the signal integrity characteristic degradation of the semiconductor package 10.

In other words, the molding film 300 of the semiconductor package 10 of the present disclosure includes both the first molding layer 301 and the second molding layer 302, thereby simultaneously maintaining the heat dissipation characteristics and preventing the signal integrity characteristic degradation.

According to one or more embodiments, a second molding layer 302 may be positioned between the first redistribution structure 200 and the first molding layer 301. For example, the second molding layer 302 may be positioned on the first redistribution structure 200, and the first molding layer 301 may be positioned on the second molding layer 302. For example, the second molding layer 302 may be positioned over at least a portion of the first redistribution structure 200, and the first molding layer 301 may be in contact with the second molding layer 302 and positioned over the second molding layer 302. In this case, in the region where the second molding layer 302 is not positioned, the first molding layer 301 may be in contact with the first redistribution structure 200.

However, this is not limited to this, and other components may be placed between the first molding layer 301 and the second molding layer 302. Additionally, other components may be placed between the first molding layer 301 and the first redistribution structure 200.

As illustrated in FIG. 1, the second molding layer 302 according to one or more embodiments may be positioned over the entire region around the semiconductor chip 100 from a planar area perspective. In other words, from a flat area perspective, the second molding layer 302 may be positioned on the entire region excluding the semiconductor chip 100 on the first redistribution structure 200. In other words, the second molding layer 302 may cover the region around the semiconductor chip 100 in a plane perspective. The second molding layer 302 may not overlap the semiconductor chip 100 in the vertical direction.

According to one or more embodiments, the first molding layer 301 and the second molding layer 302 may have different thicknesses along the vertical direction. According to one or more embodiments, at a portion where the first molding layer 301 and the second molding layer 302 overlap in the vertical direction, the first thickness t1 of the first molding layer 301 along the vertical direction may be greater than the second thickness t2 of the second molding layer 302 along the vertical direction.

For example, the first thickness t1 may range from about 15 times to about 30 times of the second thickness t2. However, this is only an example presented for explanation and the embodiment is not limited thereto. For example, the first thickness t1 may range from about 30 times to about 100 times of the second thickness t2.

According to one or more embodiments, the second thickness t2 of the second molding layer 302 may be about 10 μm or more.

As described above, according to the present disclosure, the first thickness t1 of the first molding layer 301 of the semiconductor package 10 along the vertical direction is in a range of about 15 to about 30 times of the second thickness t2 of the second molding layer 302 along the vertical direction, thereby improving the heat dissipation characteristics of the semiconductor package 10.

In addition, as described above, since the second thickness t2 of the second molding layer 302 of the semiconductor package 10 according to the present disclosure along the vertical direction is approximately 10 μm or more, the degradation of the signal integrity characteristic in the semiconductor package 10 may be prevented.

According to one or more embodiments, the chip pad 120 of the semiconductor chip 100 may be electrically connected to the substrate pad 222 of the first redistribution structure 200 via the connection terminal 150.

According to one or more embodiments, the power/ground chip connection terminal 150a may be interposed between the power/ground chip pad 120a of the semiconductor chip 100 and the power/ground substrate pad 222a of the first redistribution structure 200. For example, the power/ground chip connection terminal 150a may electrically connect the power/ground chip pad 120a of the semiconductor chip 100 to the power/ground line pattern 221a of the first redistribution structure 200.

Additionally, the signal chip connection terminal 150b may be interposed between the signal chip pad 120b of the semiconductor chip 100 and the signal substrate pad 222b of the first redistribution structure 200. For example, the signal chip connection terminal 150b may electrically connect the signal chip pad 120b of the semiconductor chip 100 to the signal line pattern 221b of the first redistribution structure 200.

According to one or more embodiments, each of the power/ground chip connection terminal 150a and the signal chip connection terminal 150b may be provided in plurality, and the plurality of power/ground chip connection terminals 150a and the plurality of signal chip connection terminals 150b may be arranged in a zigzag structure or a honeycomb structure on the lower surface of the semiconductor substrate.

According to one or more embodiments, the power/ground chip connection terminal 150a and the signal chip connection terminal 150b may be solder balls including at least one material among copper (Cu), aluminum (Al), silver (Ag), tin (Tin), and gold (Au).

According to one or more embodiments, the external connection terminals 500 may be arranged on the lower surface of the first redistribution structure 200. The external connection terminals 500 may be provided on the lower surface of the external connection pad 230. The external connection terminals 500 may be spaced in the horizontal direction. The external connection terminals 500 may include a solder material. For example, the external connection terminals 500 may include tin (Sn), bismuth (Bi), lead (Pb), silver (Ag), or an alloy thereof.

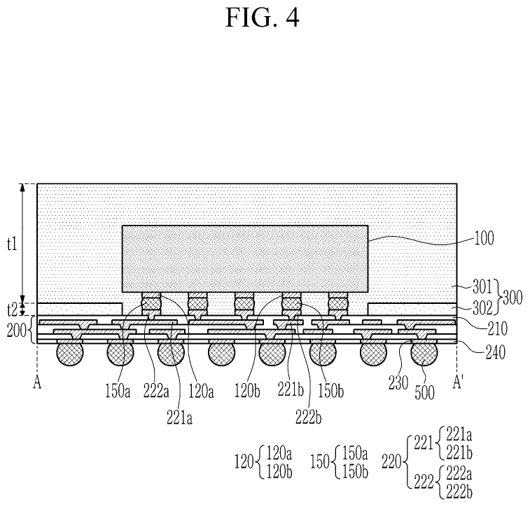

FIG. 4 is a cross-sectional view taken along a line A-A′ of FIG. 1 according to one or more embodiments.

In the following, and any similar or overlapping content described with reference to FIG. 1 to FIG. 3 will be briefly explained or omitted, and the differences will be mainly explained.

Referring to FIG. 4, the first redistribution structure 200 of the semiconductor package 10 may further include a first insulation layer 210, a first redistribution pattern 220 including a line pattern 221 and a substrate pad 222, an external connection pad 230, and a substrate protection layer 240.

According to one or more embodiments, the first redistribution structure 200 may include a plurality of mutually stacked first insulation layers 210. FIG. 4 illustrates the stacking of three first insulation layers 210, but the present disclosure is not limited thereto. The number of the first insulation layers 210 stacked within the first redistribution structure 200 may be provided in various ways as required.

The first insulation layers 210 may include organic materials, such as, for example, a photosensitivity insulating (a photo-imageable dielectric, PID) material. the photosensitivity insulating material may be polymer. The photosensitivity insulating material may include, for example, at least one of a photosensitivity polyimide, a polybenzooxazole, a phenol-based polymer, and a benzocyclobutene-based polymer. FIG. 4 shows the boundary between the first insulation layers 210, but the present disclosure is not limited thereto. According to one or more embodiments, the interface between the adjacent first insulation layers 210 may be indistinguishable.

According to one or more embodiments, the first redistribution pattern 220 may include a line pattern 221 and a substrate pad 222.

According to one or more embodiments, the line pattern 221 may include a power/ground line pattern 221a and a signal line pattern 221b. According to one or more embodiments, the substrate pad 222 may include a power/ground substrate pad 222a and a signal substrate pad 222b.

According to one or more embodiments, the power/ground line pattern 221a may extend in the horizontal direction within the first insulation layer 210 and be connected to the power/ground substrate pad 222a.

Additionally, the signal line pattern 221b may extend in a horizontal direction inside the first insulation layer 210 and be connected to the signal substrate pad 222b.

According to one or more embodiments, the material of the power/ground line pattern 221a and the signal line pattern 221b may include copper (Cu). For example, the material of the power/ground line pattern 221a and the signal line pattern 221b may include at least one of an electrolytically deposited (ED) copper, a rolled-annealed (RA) copper foil, a stainless steel foil, an aluminum foil, ultra-thin copper foils, a sputtered copper, copper alloys, nickel, stainless steel, and beryllium copper.

According to one or more embodiments, the power/ground line pattern 221a and the signal line pattern 221b can be arranged at substantially the same level within the first insulation layer 210. That is, the height formed by the power/ground line pattern 221a in the vertical direction from the lower surface of the first redistribution structure 200 may be substantially the same as the height formed by the signal line pattern 221b in the vertical direction from the lower surface of the first redistribution structure 200.

According to one or more embodiments, each of the power/ground line pattern 221a and the signal line pattern 221b may be provided in multiples. In various embodiments, the power/ground line pattern 221a and the signal line pattern 221b may be arranged in various ways as needed.

The power/ground substrate pad 222a may be arranged on the first insulation layer 210 and be connected to the power/ground line pattern 221a. Additionally, at least a portion of the power/ground substrate pad 222a may protrude outside the first insulation layer 210, and the protruded power/ground substrate pad 222a may be in contact with the power/ground chip connection terminal 150a.

According to one or more embodiments, the power/ground substrate pad 222a may be arranged at substantially the same level as the power/ground line pattern 221a. However, without being limited to the above, the power/ground substrate pad 222a may be arranged at a higher level than the power/ground line pattern 221a.

The signal substrate pad 222b may be arranged on the first insulation layer 210 and be connected to the signal line pattern 221b. Additionally, at least a portion of the signal substrate pad 222b may protrude outside the first insulation layer 210, and the protruded signal substrate pad 222b may be in contact with the signal chip connection terminal 150b.

According to one or more embodiments, the signal substrate pad 222b may be arranged at substantially the same level as the signal line pattern 221b. However, without being limited to the above, the signal substrate pad 222b may be arranged at a higher level than the signal line pattern 221b.

According to one or more embodiments, each of the power/ground substrate pad 222a and the signal substrate pad 222b may be provided in plural. Additionally, the plurality of power/ground substrate pads 222a and the plurality of signal substrate pads 222b may be arranged in a zigzag structure or a honeycomb structure.

According to one or more embodiments, the plurality of power/ground substrate pads 222a may overlap the power/ground chip pad 120a of the semiconductor chip 100 in the vertical direction, and the plurality of signal substrate pads 222b may overlap the signal chip pad 120b of the semiconductor chip 100 in the vertical direction.

According to one or more embodiments, the external connection pad 230 may be provided below the lowermost first insulation layer 210 among the first insulation layers 210. The external connection pads 230 may be spaced apart from each other in the horizontal direction. The external connection pad 230 may be connected to the first redistribution patterns 220. For example, the via portion of the lowest first redistribution pattern 220 among the first redistribution patterns 220 may penetrate the first insulation layer 210 and be connected to the external connection pad 230. The external connection pad 230 may be electrically connected to the substrate pad 222 via the first redistribution pattern 220. The external connection pad 230 may include a conductive material. For example, the external connection pad 230 may include copper (Cu).

According to one or more embodiments, the substrate protection layer 240 may be provided beneath the lowermost first insulation layer 210. The substrate protection layer 240 may surround the external connection pad 230 on the lower surface of the lowermost first insulation layer 210. The substrate protection layer 240 may expose the lower surface of the external connection pad 230. The substrate protection layer 240 may include a solder resist material.

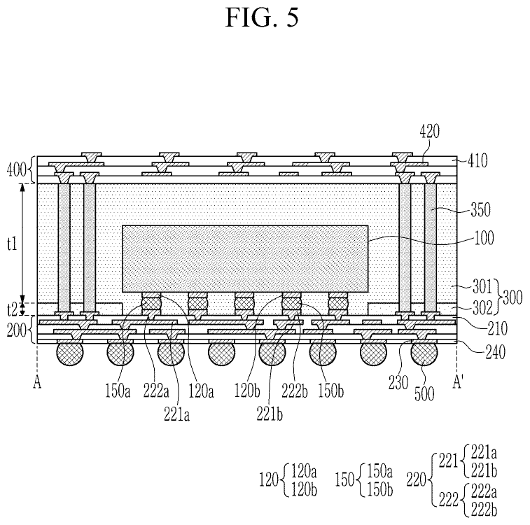

FIG. 5 is a cross-sectional view taken along a line A-A′ of FIG. 1 according to one or more embodiments.

In the following, the similar or overlapping content to the above described with reference to FIG. 1 to FIG. 4 will be briefly described or omitted, and differences will be mainly explained.

Referring to FIG. 5, the semiconductor package 10 may further include a second redistribution structure 400, and connection structures 350 connecting the first redistribution structure 200 and the second redistribution structure 400.

According to one or more embodiments, the connection structures 350 may be placed on the first redistribution structure 200. The connection structures 350 may be placed on the substrate pad 222 of the first redistribution structure 200. The connection structures 350 may vertically penetrate the molding film 300 to connect the first redistribution structure 200 and the second redistribution structure 400. The lower surface of the connection structures 350 may be in contact with the upper surface of the substrate pad 222. The connection structures 350 may be electrically connected to the semiconductor chip 100 through the first redistribution patterns 220 of the first redistribution structure 200. The upper surface of the connection structures 350 may be coplanar with the upper surface of the molding film 300. The connection structures 350 may be spaced from each other on the first redistribution structure 200. The connection structures 350 may be spaced apart from the side of the semiconductor chip 100. The connection structures 350 may be arranged to surround the side of the semiconductor chip 100. The side surfaces of the connection structures 350 may be landfilled by the molding film 300.

According to one or more embodiments, the second redistribution structure 400 may be provided on the molding film 300. The second redistribution structure 400 may cover the upper surface of the molding film 300 and the upper surfaces of the connection structures 350.

According to one or more embodiments, the second redistribution structure 400 may include a plurality of second insulation layers 410 that are mutually stacked. FIG. 5 illustrates the stacking of three second insulation layers 410, but the present disclosure is not limited thereto. The number of the second insulation layers 410 stacked within the second redistribution structure 400 may vary if necessary. The second insulation layers 410 may include organic materials, such as, for example, photosensitivity insulating (photo-imageable dielectric, PID) materials. The photosensitivity insulating material may be a polymer. The photosensitivity insulating material may include, for example, at least one of a photosensitivity polyimide, a polybenzooxazole, a phenol-based polymer, and a benzocyclobutene-based polymer. FIG. 5 shows the boundaries between the second insulation layers 410, but the present disclosure is not limited thereto. According to one or more embodiments, the interface between the adjacent second insulation layers 410 may be indistinguishable.

According to one or more embodiments, the second redistribution patterns 420 may be provided within the second insulation layers 410. The second redistribution patterns 420 may have a second via portion and a second wiring portion that are integrally connected to each other. The second wiring part may be a pattern for a horizontal connection within the second redistribution structure 400. The second via portion may be a portion that vertically connects the second redistribution patterns 420 within the second insulation layers 410. The second wiring portion may be provided on the second via portion. The second wiring part may be connected to the second via part without any interface. The width of the second wiring section may be larger than the width of the second via section. In other words, each of the second redistribution patterns 420 may have a cross-section of a T shape. The second wiring portion of the second redistribution patterns 420 can be positioned on the upper surface of the second insulation layers 410. The second via portion of the second redistribution patterns 420 may pass through the second insulation layers 410 and be connected to the second wiring portion of another second redistribution pattern 420 positioned underneath. Among the second redistribution patterns 420, the uppermost second redistribution pattern 420 may be exposed on the upper surface of the second redistribution structure 400. The uppermost second redistribution pattern 420 may correspond to a pad for mounting an additional semiconductor chip or a semiconductor package on the second redistribution structure 400. The second redistribution patterns 420 may include a conductive material. For example, the second redistribution patterns 420 may include copper (Cu).

Seed patterns may be placed on the undersides of the second redistribution patterns 420. For example, the seed patterns may cover the lower surface of the second via portion, the side wall, and the lower surface of the second wiring portion of the corresponding second redistribution patterns 420, respectively. The seed patterns may include a different material than the second redistribution patterns 420. For example, the seed patterns may include copper (Cu), titanium (Ti) or alloys thereof. The second redistribution patterns 420 may further include a barrier layer that prevents a diffusion of a material included in the second redistribution patterns 420. The barrier layer may include titanium nitride (TiN) or tantalum nitride (TaN).

According to one or more embodiments, the second redistribution patterns 420 may be connected to the connection structures 350. Among the second redistribution patterns 420, the lowermost second redistribution pattern 420 may be in contact with the upper surface of the connection structures 350. The second redistribution patterns 420 may be electrically connected to the semiconductor chip 100 through the connection structures 350 and the first redistribution patterns 220.

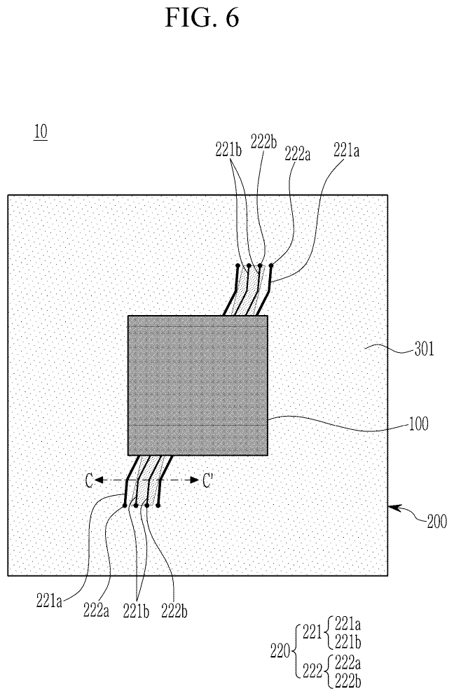

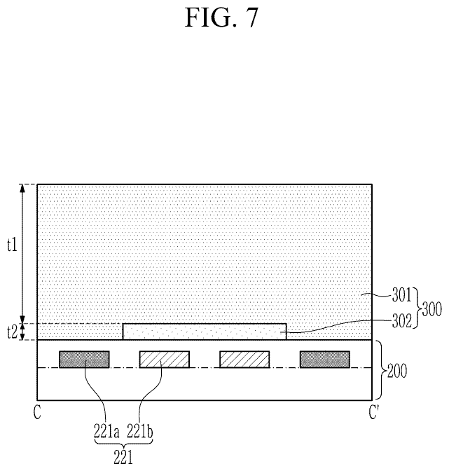

FIG. 6 is a top plan view of a semiconductor package according to one or more embodiments. FIG. 7 is a cross-sectional view taken along a line C-C′ of FIG. 6 according to one or more embodiments.

In the following, any content that is similar or overlapping with the above described with reference to FIG. 1 to FIG. 5 will be briefly described or omitted, and the differences will be mainly explained.

Referring to FIG. 6 and FIG. 7 together, a semiconductor package 10 according to one or more embodiments of the present disclosure may include a semiconductor chip 100, a first redistribution structure 200 including a first redistribution pattern 220, and a molding film 300.

According to one or more embodiments, the first redistribution pattern 220 may include a line pattern 221 and a substrate pad 222.

According to one or more embodiments, the line pattern 221 may include a power/ground line pattern 221a and a signal line pattern 221b. According to one or more embodiments, the substrate pad 222 may include a power/ground substrate pad 222a and a signal substrate pad 222b. According to one or more embodiments, the power/ground line pattern 221a may be connected to the power/ground substrate pad 222a, and the signal line pattern 221b may be connected to the signal substrate pad 222b.

According to one or more embodiments, the molding film 300 may be disposed on the first redistribution structure 200. The molding film 300 may surround the semiconductor chip 100 on the first redistribution structure 200.

According to one or more embodiments, the molding film 300 may include a first molding layer 301 and a second molding layer 302. As described above, the first molding layer 301 may include a material having a first dielectric constant, and the second molding layer 302 may include a material having a second dielectric constant smaller than the first dielectric constant.

In some embodiments, the first molding layer 301 may include a high-dielectric material having a dielectric constant of greater than about 7. For example, the first dielectric constant may have a value within the range of about 7 to about 1000. According to one or more embodiments, the second molding layer 302 may include a low-dielectric material having a dielectric constant of less than about 7. For example, the second dielectric constant may have a value within a range of about 1 to about 7.

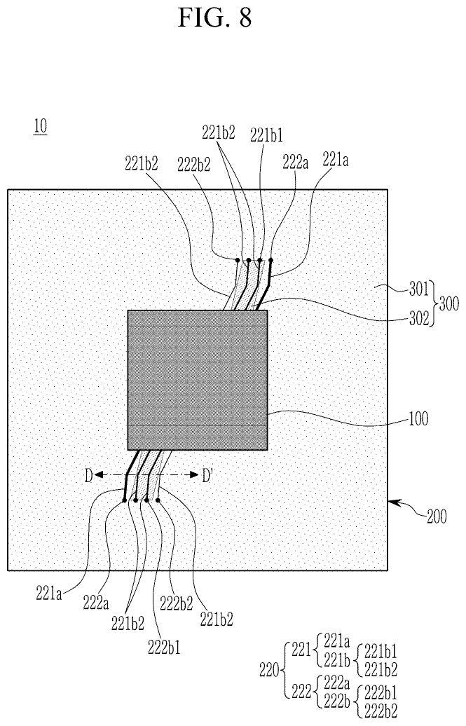

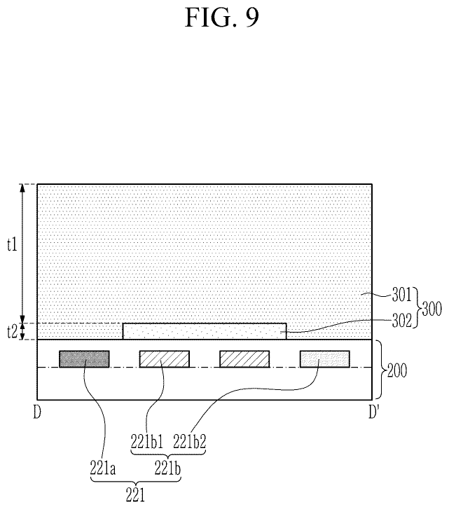

As illustrated in FIG. 6 and FIG. 7, the second molding layer 302 according to one or more embodiments may overlap the signal line pattern 221b in the vertical direction. For example, the second molding layer 302 may overlap the first signal line pattern 221b1, which transmits a high-speed signal to be described later, in the vertical direction. Specific details regarding the second molding layer 302 overlapping the first signal line pattern 221b1 in the vertical direction are described in detail later with reference to FIG. 8 and FIG. 9.

According to one or more embodiments, the second molding layer 302 may not overlap a region where the signal line pattern 221b is not positioned in the vertical direction. In other words, the second molding layer 302 may not overlap a region outside the first signal line pattern 221b1 in a plane perspective. For example, the second molding layer 302 may not overlap the power/ground line pattern 221a in the vertical direction. In other words, the second molding layer 302 may overlap the signal line pattern 221b in the vertical direction, but may not overlap the power/ground line pattern 221a in the vertical direction. Additionally, the second molding layer 302 may not overlap the semiconductor chip 100 in the vertical direction.

According to one or more embodiments, the first molding layer 301 may be positioned over the entire region in a plane perspective. According to one or more embodiments, a second molding layer 302 may be positioned between the first redistribution structure 200 and the first molding layer 301. For example, the second molding layer 302 may be positioned on the signal line pattern 221b, and the first molding layer 301 may be positioned on the second molding layer 302. In the present embodiment, the second molding layer 302 may be positioned between the first molding layer 301 and the first redistribution structure 200 on the signal line pattern 221b, and the second molding layer 302 may not be positioned between the first molding layer 301 and the first redistribution structure 200 on the power/ground line pattern 221a. In other words, in the region where the second molding layer 302 is not positioned, the first molding layer 301 may be in directly contact with the first redistribution structure 200.

According to one or more embodiments, the first molding layer 301 and the second molding layer 302 may have the different thicknesses along the vertical direction. According to one or more embodiments, the second molding layer 302, which overlaps the signal line pattern 221b in the vertical direction, may have a second thickness t2. The first molding layer 301 on the second molding layer 302 may have a first thickness t1 that is different from the second thickness t2.

According to one or more embodiments, the first thickness t1 of the first molding layer 301 positioned on the second molding layer 302 may be greater than the second thickness t2 of the second molding layer 302. For example, the first thickness t1 may range from about 15 times to about 30 times of the second thickness t2. However, this is only an example presented for explanation and the embodiment is not limited thereto.

According to one or more embodiments, the second thickness t2 along the vertical direction of the second molding layer 302 that overlaps the signal line pattern 221b in the vertical direction may be about 10 μm or more.

As described above, since the second molding layer 302 of the semiconductor package 10 according to the present disclosure overlaps the signal line pattern 221b in the vertical direction, the degradation of the signal integrity characteristic in the semiconductor package 10 may be prevented.

FIG. 8 is a top plan view of a semiconductor package according to one or more embodiments. FIG. 9 is a cross-sectional view taken along a line D-D′ of FIG. 8 according to one or more embodiments.

In the following, similar or overlapping content to the above described with reference to FIG. 1 to FIG. 7 will be briefly described or omitted, and differences will be mainly explained.

Referring to FIG. 8 and FIG. 9 together, a semiconductor package 10 according to one or more embodiments of the present disclosure may include a semiconductor chip 100, a first redistribution structure 200 including a first redistribution pattern 220, and a molding film 300.

According to one or more embodiments, the first redistribution pattern 220 may include a line pattern 221 and a substrate pad 222.

According to one or more embodiments, the line pattern 221 may include a power/ground line pattern 221a and a signal line pattern 221b. According to one or more embodiments, the substrate pad 222 may include a power/ground substrate pad 222a and a signal substrate pad 222b. According to one or more embodiments, the power/ground line pattern 221a may be connected to the power/ground substrate pad 222a, and the signal line pattern 221b may be connected to the signal substrate pad 222b.

According to one or more embodiments, the signal line pattern 221b may include a first signal line pattern 221b1 transmitting a first signal and a second signal line pattern 221b2 transmitting a second signal. For example, the first signal transmitted via the first signal line pattern 221b1 may be faster than the second signal transmitted via the second signal line pattern 221b2. For example, the first signal may be a high-speed signal and the second signal may be a normal signal or a low-speed signal. In other words, the second signal line pattern 221b2 may be configured to transmit at a lower speed than the first signal line pattern 221b1.

According to one or more embodiments, the molding film 300 may be disposed on the first redistribution structure 200. The molding film 300 may surround the semiconductor chip 100 on the first redistribution structure 200.

According to one or more embodiments, the molding film 300 may include a first molding layer 301 having a first dielectric constant and a second molding layer 302 having a second dielectric constant smaller than the first dielectric constant.

As illustrated in FIG. 8 and FIG. 9, the second molding layer 302 according to one or more embodiments may overlap the first signal line pattern 221b1 in the vertical direction. In other words, the second molding layer 302 may overlap the first signal line pattern 221b1, which transmits a high-speed signal, in the vertical direction.

According to one or more embodiments, the second molding layer 302 may not overlap a region where the first signal line pattern 221b1 is not positioned in the vertical direction. For example, the second molding layer 302 may not overlap the power/ground line pattern 221a in the vertical direction. Also, for example, the second molding layer 302 may not overlap the second signal line pattern 221b2 in the vertical direction. In other words, the second molding layer 302 may overlap the first signal line pattern 221b1 that transmits a high-speed signal in the vertical direction, but may not overlap the second signal line pattern 221b2 and the power/ground line pattern 221a that transmit a low-speed or general signal in the vertical direction.

According to one or more embodiments, the first molding layer 301 may be positioned over the entire region from a plane perspective. According to one or more embodiments, a second molding layer 302 may be positioned between the first redistribution structure 200 and the first molding layer 301. For example, the second molding layer 302 may be positioned on the first signal line pattern 221b1, and the first molding layer 301 may be positioned on the second molding layer 302. In the present embodiment, the second molding layer 302 may be positioned between the first molding layer 301 and the first redistribution structure 200 on the first signal line pattern 221b1, and the second molding layer 302 may not be positioned between the first molding layer 301 and the first redistribution structure 200 on the second signal line pattern 221b2 and the power/ground line pattern 221a. In other words, in the region where the second molding layer 302 is not positioned, the first molding layer 301 may be in directly contact with the first redistribution structure 200.

As described above, since the second molding layer 302 of the semiconductor package 10 according to the present disclosure overlaps the first signal line pattern 221b1 transmitting the high-speed signal in the vertical direction, the high-speed signal transmission characteristics in the semiconductor package 10 may be improved.

According to one or more embodiments, the first molding layer 301 and the second molding layer 302 may have different thicknesses along the vertical direction. According to one or more embodiments, the second molding layer 302, which overlaps the first signal line pattern 221b1 in the vertical direction, may have a second thickness t2. The first molding layer 301 on the second molding layer 302 may have a first thickness t1 that is different from the second thickness t2.

According to one or more embodiments, the first thickness t1 of the first molding layer 301 positioned on the second molding layer 302 may be greater than the second thickness t2 of the second molding layer 302. For example, the first thickness t1 may range from about 15 times to about 30 times of the second thickness t2. However, this is only an example presented for explanation and the embodiment is not limited thereto.

According to one or more embodiments, the second thickness t2 along the vertical direction of the second molding layer 302 that overlaps the first signal line pattern 221b1 in the vertical direction may be about 10 μm or more.

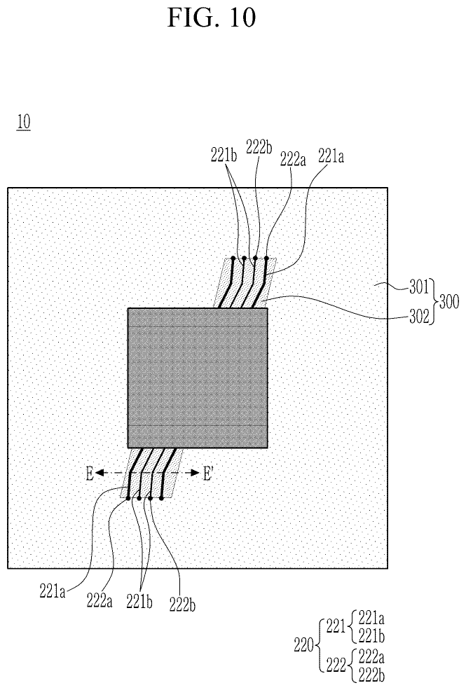

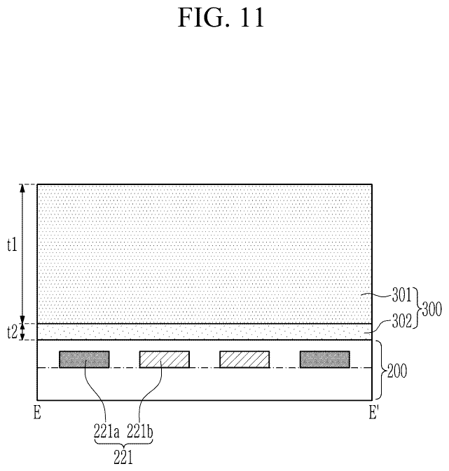

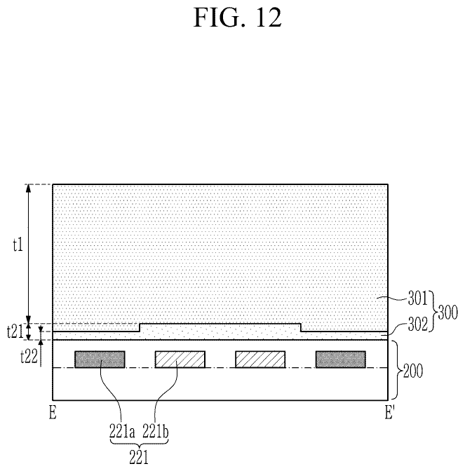

FIG. 10 is a top plan view of a semiconductor package according to one or more embodiments. FIG. 11 is a cross-sectional view taken along a line E-E′ of FIG. 10 according to one or more embodiments. FIG. 12 is a cross-sectional view taken along a line E-E′ of FIG. 10 according to one or more embodiments.

In the following, any content that is similar or overlapping with the above described with reference to FIG. 1 to FIG. 9 will be briefly described or omitted, and the differences will be mainly explained.

Referring to FIG. 10 to FIG. 12 together, a semiconductor package 10 according to one or more embodiments of the present disclosure may include a semiconductor chip 100, a first redistribution structure 200 including a first redistribution pattern 220, and a molding film 300.

According to one or more embodiments, the first redistribution pattern 220 may include a line pattern 221 and a substrate pad 222.

According to one or more embodiments, the line pattern 221 may include a power/ground line pattern 221a and a signal line pattern 221b. According to one or more embodiments, the substrate pad 222 may include a power/ground substrate pad 222a and a signal substrate pad 222b. According to one or more embodiments, the power/ground line pattern 221a may be connected to the power/ground substrate pad 222a, and the signal line pattern 221b may be connected to the signal substrate pad 222b.

According to one or more embodiments, the molding film 300 may be disposed on the first redistribution structure 200. The molding film 300 may surround the semiconductor chip 100 on the first redistribution structure 200.

According to one or more embodiments, the molding film 300 may include a first molding layer 301 having a first dielectric constant and a second molding layer 302 having a second dielectric constant smaller than the first dielectric constant.

As illustrated in FIG. 10 to FIG. 12, the second molding layer 302 according to one or more embodiments may overlap the power/ground line pattern 221a and the signal line pattern 221b in the vertical direction. For example, the second molding layer 302 may overlap the power/ground line pattern 221a and the signal line pattern 221b in the vertical direction.

According to one or more embodiments, the second molding layer 302 may not overlap a region where the power/ground line pattern 221a and the signal line pattern 221b are not positioned in the vertical direction.

According to one or more embodiments, the first molding layer 301 may be positioned over the entire region from a plane perspective. According to one or more embodiments, a second molding layer 302 can be positioned between the first redistribution structure 200 and the first molding layer 301. For example, the second molding layer 302 may be positioned on the power/ground line pattern 221a and the signal line pattern 221b, and the first molding layer 301 may be positioned on the second molding layer 302. In the present embodiment, the second molding layer 302 may be positioned between the first molding layer 301 and the first redistribution structure 200 on the power/ground line pattern 221a and the signal line pattern 221b, and the second molding layer 302 may not be positioned between the first molding layer 301 and the first redistribution structure 200 on the region where the power/ground line pattern 221a and the signal line pattern 221b are positioned. In other words, in the region where the second molding layer 302 is not positioned, the first molding layer 301 may be in directly contact with the first redistribution structure 200.

According to one or more embodiments, the first molding layer 301 and the second molding layer 302 may have different thicknesses along the vertical direction.

Referring to FIG. 11, the second molding layer 302, which overlaps the power/ground line pattern 221a and the signal line pattern 221b in the vertical direction, may have a second thickness t2. The first molding layer 301 on the second molding layer 302 may have a first thickness t1 that is different from the second thickness t2.

According to one or more embodiments, the first thickness t1 of the first molding layer 301 positioned on the second molding layer 302 may be greater than the second thickness t2 of the second molding layer 302. For example, the first thickness t1 may range from about 15 times to about 30 times of the second thickness t2. However, this is only an example presented for explanation and the embodiment is not limited thereto.

According to one or more embodiments, the second thickness t2 along the vertical direction of the second molding layer 302 that overlaps the signal line pattern 221b in the vertical direction may be about 10 μm or more.

Referring to FIG. 12, the second molding layer 302 may have a twenty-first thickness t21 over the signal line pattern 221b and a twenty-second thickness t22 over the power/ground line pattern 221a. For example, the twenty-first thickness t21 may be greater than the twenty-second thickness t22. In other words, the twenty-first thickness t21 of the second molding layer 302 on the signal line pattern 221b may be greater than the twenty-second thickness t22 of the second molding layer 302 on the power/ground line pattern 221a.

According to one or more embodiments, the first molding layer 301 on the second molding layer 302, which overlaps the signal line pattern 221b in the vertical direction, may have a first thickness t1 that is different from the second thickness t2.

According to one or more embodiments, the first thickness t1 of the first molding layer 301 positioned on the second molding layer 302 that overlaps the signal line pattern 221b in the vertical direction may be greater than the twenty-first thickness t21. For example, the first thickness t1 may range from about 15 times to about 30 times of the twenty-first thickness t21. However, this is only an example presented for explanation and the embodiment is not limited thereto.

According to one or more embodiments, the twenty-first thickness t21 along the vertical direction of the second molding layer 302, which overlaps the signal line pattern 221b in the vertical direction, may be about 10 μm or more.

As described above, since the second molding layer 302 of the semiconductor package 10 according to the present disclosure has the thickness of about 10 μm or more on the signal line pattern 221b, the degradation of the signal integrity characteristic in the semiconductor package 10 may be prevented.

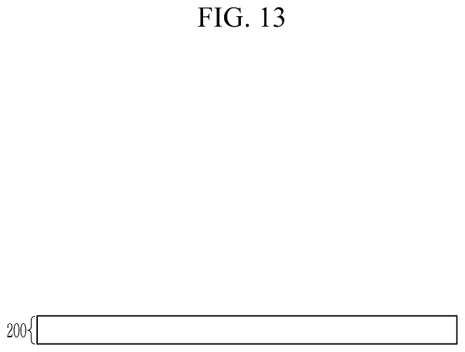

FIG. 13 to FIG. 16 are views for explaining a manufacturing method of a semiconductor chip according to one or more embodiments.

The manufacturing method of the semiconductor package described in FIG. 13 to FIG. 16 is only exemplary, and a formation order and a formation method of each component are not limited to the present embodiment. Furthermore, various configurations of elements not disclosed in the present embodiment may be additionally formed in each between the components.

Meanwhile, in FIG. 13 to FIG. 16, the same reference symbols as in FIG. 1 to FIG. 12 indicate the same members, and redundant descriptions of these are omitted here to simplify the explanation.

Referring to FIG. 13, a method for manufacturing a semiconductor package of the present disclosure may include a step in which a first redistribution structure 200 is provided.

The first redistribution structure 200 may include a plurality of first insulation layers, a plurality of first redistribution patterns, and a plurality of vias for electrical connections between the plurality of first redistribution patterns. The first insulation layer may include at least one of a silicon-based insulator such as silicon oxide or silicon nitride, a polymer such as PBO, BCB or polyimide, and a nitride such as PSG or BPSG. The first redistribution pattern may be formed by at least one of copper, aluminum, nickel, titanium, and alloys thereof. The vias mat be formed of copper, a copper-containing composition or a copper alloy. Alternatively, it may be formed from materials such as aluminum, nickel, etc.

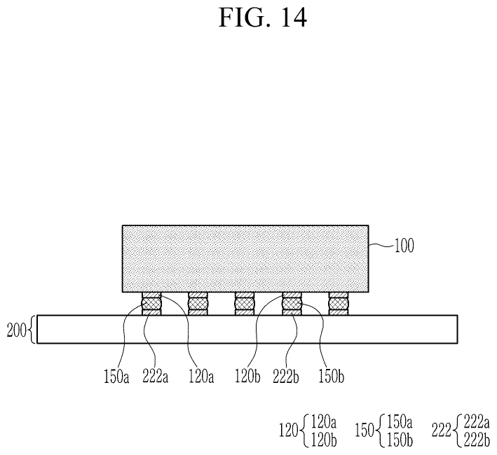

Referring to FIG. 14, the method for manufacturing the semiconductor package of the present disclosure may include a step of placing a semiconductor chip on the first redistribution structure 200.

According to one or more embodiments, a semiconductor chip 100 may include a semiconductor substrate having an active layer, and a chip pad 120 disposed on a lower surface of the semiconductor substrate.

According to one or more embodiments, the semiconductor chip 100 may be placed on the first redistribution structure 200. The semiconductor chip 100 may be bonded on the first redistribution structure 200. For example, the semiconductor chip 100 may be electrically connected to the first redistribution structure 200 via the connection terminal 150. The chip pad 120 of the semiconductor chip 100 may be electrically connected to the substrate pad 222 of the first redistribution structure 200 through the connection terminal 150.

Specifically, the semiconductor chip 100 may be mounted on the first redistribution structure 200 through a flip chip bonding process. In one or more embodiments, the power/ground chip connection terminal 150a attached to the power/ground chip pad 120a of the semiconductor chip 100 may be in contact with the power/ground substrate pad 222a of the first redistribution structure 200. Additionally, the signal chip connection terminal 150b attached to the signal chip pad 120b of the semiconductor chip 100 can be in contact with the signal substrate pad 222b of the first redistribution structure 200.

In the drawing, only one semiconductor chip 100 is shown, but it is not limited to this, and a plurality of semiconductor chips may be arranged.

For example, the chip pads 120 may be formed of aluminum (Al) or copper (Cu). In some embodiments, the chip pads 120 may be formed using a plating method (e.g., s pulse plating and a DC plating methods) or a deposition method.

It may further form a protective layer to protect the semiconductor chip 100. The protective layer may serve to an ensure insulation between the chip pads 120 formed spaced apart from each other. For example, the protective layer may be a silicon oxide layer or a silicon nitride layer.

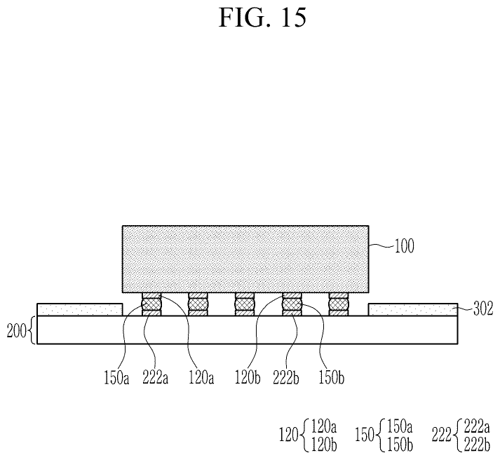

Referring to FIG. 15, the method for manufacturing the semiconductor package of the present disclosure may include a step of forming a second molding layer 302 on the first redistribution structure 200.

According to one or more embodiments, a second material having a second dielectric constant may be deposited on at least some region of the first redistribution structure 200. According to one or more embodiments, the second material may be composed of a low-dielectric material. For example, the second dielectric constant of the second material may have a value within a range of about 1 to about 7.

According to one or more embodiments, the second material may be applied to the entire region around the semiconductor chip 100 in a plane perspective. According to one or more embodiments, the second material may be coated to the region that overlaps the power/ground line pattern (e.g., the power/ground line pattern 221a of FIG. 1 and FIG. 2) and the signal line pattern (e.g., the signal line pattern 221b of FIG. 1 and FIG. 2). in the vertical direction

In other words, the second material may be coated to the region where it does not overlap the region where the signal line pattern 221b is not positioned in the vertical direction.

According to one or more embodiments, the second material may be coated to a region that overlaps the signal line pattern 221b in the vertical direction, and may not be coated to a region that overlaps the power/ground line pattern 221a in the vertical direction. In other words, the second material may not be coated to a region that does not overlap a region where the signal line pattern 221b is not positioned in the vertical direction.

According to one or more embodiments, the second material may be coated to a region that overlaps the first signal line pattern (e.g., first signal line pattern 221b1 of FIG. 8 and FIG. 9) transmitting a high-speed signal, in the vertical direction and not be coated to a region that overlaps the power/ground line pattern 221a and the second signal line pattern (e.g., the second signal line pattern 221b2 of FIG. 8 and FIG. 9) transmitting a general signal or a low-speed signal. in the vertical direction. In other words, the second material may not be coated to the region that does not overlap the region where the first signal line pattern 221b1 is not positioned in the vertical direction.

According to one or more embodiments, a second molding layer 302 can be formed through a curing process. For example, the curing process may include a thermal curing using heat or a photocuring using ultraviolet rays.

As the curing process progresses, the second molding layer 302 may be formed over the entire region around the semiconductor chip 100 in a plane perspective. According to one or more embodiments, the second molding layer 302 may be formed in a region that overlaps the power/ground line pattern 221a and the signal line pattern 221b in the vertical direction. In other words, the second molding layer 302 may be formed even in a region where does not overlap a region where the signal line pattern 221b is not positioned in the vertical direction.

According to one or more embodiments, the second molding layer 302 may be formed in a region that overlaps the signal line pattern 221b in the vertical direction, and may not be formed in a region that overlaps the power/ground line pattern 221a in the vertical direction. In other words, the second molding layer 302 may not be formed in a region that does not overlap a region where the signal line pattern 221b is not positioned in the vertical direction.

According to one or more embodiments, the second molding layer 302 may be formed in the region that overlaps the first signal line pattern 221b1 transmitting the high-speed signal in the vertical direction, and not formed in the region that overlaps the power/ground line pattern 221a and the second signal line pattern 221b2 transmitting the normal signal or the low-speed signal in the vertical direction. In other words, the second molding layer 302 may not be formed in the region that does not overlap the region where the first signal line pattern 221b1 is not positioned in the vertical direction.

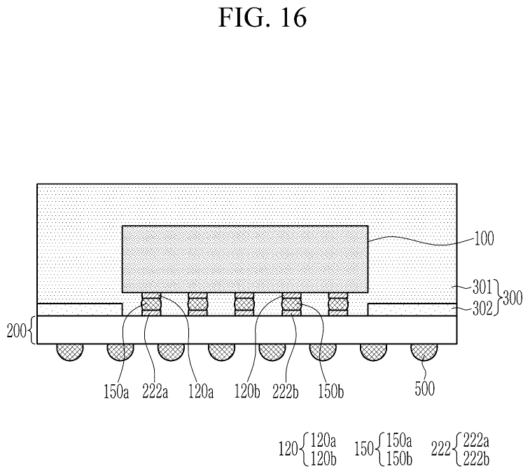

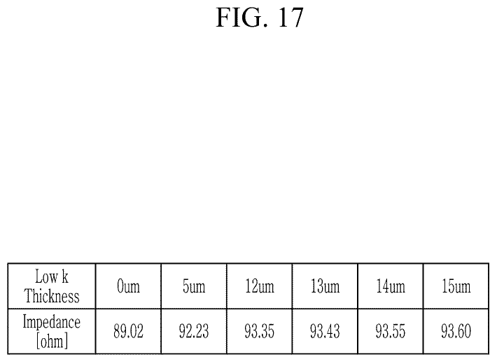

Referring to FIG. 16, the method for manufacturing the semiconductor package of the present disclosure may include forming a first molding layer 301 on the second molding layer 302.

At this time, the second molding layer 302 may be positioned between the first molding layer 301 and the first redistribution structure 200. For example, the second molding layer 302 may be formed on the first redistribution structure 200, and the first molding layer 301 may be formed on the second molding layer 302. For example, the second molding layer 302 may be formed on at least some region of the first redistribution structure 200, and the first molding layer 301 may be formed on the second molding layer 302. In this case, in the region where the second molding layer 302 is not positioned, the first molding layer 301 may be formed on the first redistribution structure 200.

According to one or more embodiments, the first molding layer 301 may surround the side and upper surfaces of the semiconductor chip 100 on the first redistribution structure 200. However, without being limited to the above, the first molding layer 301 may only surround the side surface of the semiconductor chip 100 and expose the upper surface to the outside.

According to one or more embodiments, a first material having a first dielectric constant may be implanted into the separation space between a first redistribution structure 200 and a semiconductor chip 100. For example, the first dielectric constant may have a value within the range of about 7 to about 1000. According to one or more embodiments, the separation space between the first redistribution structure 200 and the semiconductor chip 100 may be filled with an under fill material.

According to one or more embodiments, the first molding layer 301 formed between the first redistribution structure 200 and the semiconductor chip 100 may fix the semiconductor chip 100 on the first redistribution structure 200. Additionally, the first molding layer 301 may surround the side of the power/ground chip connection terminal 150a and the signal chip connection terminal 150b.

According to one or more embodiments, the method for manufacturing the semiconductor package of the present disclosure may further include a step of forming an external connection terminal 500 on the lower surface of the first redistribution structure 200.

According to one or more embodiments, the external connection terminal 500 may be electrically connected to the external connection pad (e.g., the external connection pad 230 of FIG. 2) disposed under the first insulation layer (e.g., the first insulation layer 210 of FIG. 2).

FIG. 17 is a table showing an impedance of a first signal line pattern according to a thickness of a second molding layer.

When the molding film 300, as in the present embodiment, includes the first molding layer 301 composed of the high-dielectric material, the capacitance formed between the line patterns 221 may increase. In this way, when the capacitance between the line patterns 221 increases, the impedance of the first signal line pattern 221b1 that transmits the high-speed signal decreases, so the quality of the high-speed signal may be degraded.

In this case, as in the present embodiment, since the second molding layer 302 includes the low-dielectric material, the capacitance formed between the line patterns 221 is relatively reduced, and thus the quality of the high-speed signal of the semiconductor package 10 may be improved or enhanced.

At this time, the impedance of the first signal line pattern 221b1 may vary depending on the second thickness of the second molding layer 302 along the vertical direction.

Referring to FIG. 17, as the second thickness of the second molding layer 302 along the vertical direction increases, the impedance of the first signal line pattern 221b1 increases. For example, if the second thickness of the second molding layer 302 is about 5 μm, the impedance of the first signal line pattern 221b1 may be about 92.23 Ω. Also, for example, if the second thickness of the second molding layer 302 is about 12 μm, the impedance of the first signal line pattern 221b1 can be about 93.35 Ω.

The impedance of the first signal line pattern 221b1 required to prevent the quality degradation of the high-speed signals can be approximately 93.3 Ω or higher. Accordingly, the second thickness of the second molding layer 302 required to prevent the quality degradation of the high-speed signal may be a value of approximately 10 μm or more.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor package comprising:
a redistribution structure;
a semiconductor chip on the redistribution structure; and
a molding film around the semiconductor chip,
wherein the molding film comprises:
a first molding layer having a first dielectric constant; and
a second molding layer having a second dielectric constant that is smaller than the first dielectric constant.

2. The semiconductor package of claim 1, wherein the second molding layer is between the redistribution structure and the first molding layer.

3. The semiconductor package of claim 1, wherein the redistribution structure comprises:
a first signal line pattern connected to the semiconductor chip and configured to transmit a signal at a first speed; and
a second signal line pattern configured to transmit a signal at a second speed that is lower than the first speed, and
wherein the second molding layer overlaps the first signal line pattern in a direction perpendicular to an upper surface of the redistribution structure.

4. The semiconductor package of claim 3, wherein the second molding layer covers a region around the semiconductor chip in a plane perspective.

5. The semiconductor package of claim 3, wherein the second molding layer does not overlap a region outside the first signal line pattern in a plane perspective.

6. The semiconductor package of claim 1, wherein a first thickness of the first molding layer in a first direction perpendicular to an upper surface of the redistribution structure is within a range of 15 to 30 times of a second thickness of the second molding layer in the first direction.

7. The semiconductor package of claim 6, wherein the second thickness of the second molding layer in the first direction is at least 10 μm.

8. The semiconductor package of claim 1, wherein the first molding layer comprises at least one of hafnium silicon oxynitride, hafnium oxide, zirconium oxide, tantalum oxide, titanium oxide, strontium oxide, or barium oxide.

9. A semiconductor package comprising:
a semiconductor chip comprising:
a semiconductor substrate comprising an active layer;
a power/ground chip pad on a lower surface of the semiconductor substrate; and
a signal chip pad on the semiconductor substrate;
a redistribution structure supporting the semiconductor chip, the redistribution structure comprising:
a substrate insulation layer;
a plurality of signal line patterns inside the substrate insulation layer and connected to the signal chip pad; and
a plurality of power/ground line patterns inside the substrate insulation layer on a same level as the plurality of signal line patterns and connected to the power/ground chip pad;
a first molding layer around the semiconductor chip on the redistribution structure and having a first dielectric constant; and
a second molding layer having a second dielectric constant that is smaller than the first dielectric constant.

10. The semiconductor package of claim 9, wherein the second molding layer is between the redistribution structure and the first molding layer.

11. The semiconductor package of claim 9, wherein the redistribution structure further comprises:
a first signal line pattern connected to the semiconductor chip and configured to transmit a signal at first speed; and
a second signal line pattern configured to transmit a signal at a second speed that is lower than the first speed, and
wherein the second molding layer overlaps the first signal line pattern in a direction that is perpendicular to the redistribution structure.

12. The semiconductor package of claim 11, wherein the second molding layer is covers a region around the semiconductor chip in a plane perspective.

13. The semiconductor package of claim 11, wherein the second molding layer does not overlap a region outside the first signal line pattern in a plane perspective.

14. The semiconductor package of claim 9, wherein a first thickness of the first molding layer in a first direction perpendicular to an upper surface of the redistribution structure is within a range of 15 to 30 times a second thickness of the second molding layer in the first direction.

15. The semiconductor package of claim 14, wherein the second thickness of the second molding layer the first direction is at least 10 μm.

16. The semiconductor package of claim 9, wherein the first molding layer comprises at least one of hafnium silicon oxynitride, hafnium oxide, zirconium oxide, tantalum oxide, titanium oxide, strontium oxide, or barium oxide.

17. A manufacturing method of a semiconductor package, the manufacturing method comprising:
disposing a semiconductor chip on a redistribution structure;
electrically connecting a chip pad of the semiconductor chip and a substrate pad of the redistribution structure through a connection terminal; and
forming a molding film around the semiconductor chip on the redistribution structure,
wherein the molding film comprises a first molding layer having a first dielectric constant and a second molding layer having a second dielectric constant that is smaller than the first dielectric constant.

18. The manufacturing method of the semiconductor package of claim 17, wherein the forming the molding film comprises:
forming the second molding layer on at least a portion of the redistribution structure; and
forming the first molding layer around the semiconductor chip on the second molding layer.

19. The manufacturing method of the semiconductor package of claim 18, wherein the redistribution structure comprises:
a first signal line pattern connected to the semiconductor chip and configured to transmit a signal a first speed; and
a second signal line pattern configured to transmit at a second speed that is lower than the first speed, and
wherein the forming the second molding layer comprises:
coat applying a second material having the second dielectric constant to a region that overlaps the first signal line pattern in a direction perpendicular to an upper surface of the redistribution structure; and
curing the coated second material.

20. The manufacturing method of the semiconductor package of claim 17, wherein a first thickness of the first molding layer in a first direction perpendicular to an upper surface of the redistribution structure is within a range of 15 to 30 times of a second thickness of the second molding layer in the first direction.
